(19) United States
(12) Patent Application Publication
(10) Pub. No.: US 2016/0021737 A1
(43) Pub. Date: Jan. 21, 2016

(54) ELECTRIC DEVICE MODULE AND METHOD OF MANUFACTURING THE SAME

(71) Applicant: SAMSUNG ELECTRO-MECHANICS CO., LTD., Suwon-si (KR)

(72) Inventors: Kyu Hwan OH, Suwon-Si (KR); Do Jae YOO, Suwon-Si (KR); Jong In RYU, Suwon-Si (KR); Jae Hyun LIM, Suwon-Si (KR)

(21) Appl. No.: 14/724,740

(22) Filed: May 28, 2015

(30) Foreign Application Priority Data
Jul. 17, 2014 (KR) 10-2014-0090550
Sep. 5, 2014 (KR) 10-2014-0119231

(51) Int. Cl. H05K 1/02; H05K 1/11; H05K 3/42; H05K 3/28; H05K 3/18; H05K 1/18; H05K 3/30

(52) U.S. Cl. CPC H05K 1/0296; H05K 1/181; H05K 1/115; H05K 3/303; H05K 3/284; H05K 3/188; H05K 3/423; H05K 2201/09545

(57) ABSTRACT

An electronic device module includes a board including one or more external connection electrodes and plating lines extending from the external connection electrodes by a predetermined distance; one or more electronic devices mounted on the board; a molded part sealing the electronic devices; and a plurality of connective conductors extending from the external connection electrodes and penetrating through the molded part to be disposed within the molded part.

### CROSS-REFERENCE TO RELATED APPLICATIONS

This application claims the benefit of priority to Korean Patent Application No. 10-2014-0090550 filed on Jul. 17, 2014 and 10-2014-0119231 filed on Sep. 5, 2014, with the Korean Intellectual Property Office, the disclosures of which are incorporated herein by reference.

### BACKGROUND

The present disclosure relates to an electronic device module including external terminals that maybe disposed on an exterior surface of a molded part, and a method of manufacturing the same.

In order to achieve the miniaturization and weight reduction of electronic devices, a demand exists for system-on-chip (SOC) technology, for arranging a plurality of individual devices on a single chip, system-in-package (SIP) technology for integrating a plurality of individual devices in a single package, or the like, as well as technology for decreasing respective sizes of components mounted in electronic devices.

In addition, in order to manufacture an electronic device module having a small size and high performance, a structure in which electronic components are mounted on both surfaces of a board and a structure in which external terminals are formed on both surfaces of a package have been developed.

### SUMMARY

An aspect of the present disclosure may provide an electronic device module including external terminals which are formed on a molded part of the module.

An aspect of the present disclosure may also provide a method of manufacturing an electronic device module in which connective conductors are formed in a molded part of the electronic device module through a plating process.

According to an aspect of the present disclosure, an electronic device module may include: a board including one or more external connection electrodes and plating lines extending from the external connection electrodes by a predetermined distance; one or more electronic devices mounted on the board; a molded part sealing the electronic devices; and a plurality of connective conductors extending from the external connection electrodes and penetrating through the molded part to be disposed in the molded part.

According to another aspect of the present disclosure, a method of manufacturing an electronic device module may include: preparing a board on which plating lines are formed; mounting one or more devices on the board; forming a molded part sealing the devices; forming via holes in the molded part; and forming connective conductors in the via holes by using a plating method employing the plating lines.

### BRIEF DESCRIPTION OF DRAWINGS

The above and other aspects, features and advantages of the present disclosure will be more clearly understood from the following detailed description taken in conjunction with the accompanying drawings, in which:

FIG. 1A is a top perspective view of an electronic device module according to an exemplary embodiment in the present disclosure;

FIG. 1B is a bottom perspective view of the electronic device module illustrated in FIG. 1A;

FIG. 2 is a cross-sectional view of the electronic device module illustrated in FIG. 1A;

FIG. 3 is a partially enlarged cross-sectional view of part A of FIG. 2;

FIG. 4 is a plan view of a board illustrated in FIG. 2;

FIGS. 5A through 5J are cross-sectional views illustrating a method of manufacturing the electronic device module illustrated in FIG. 1A;

FIGS. 5K through 5N are views illustrating a method of manufacturing an electronic device module according to another exemplary embodiment in the present disclosure;

FIG. 6A is atop perspective view of an electronic device module according to another exemplary embodiment in the present disclosure;

FIG. 6B is a bottom perspective view of the electronic device module illustrated in FIG. 6A;

FIG. 7 is a cross-sectional view of the electronic device module illustrated in FIG. 6A;

FIG. 8 is a partially enlarged cross-sectional view of part A of FIG. 7;

FIG. 9 is a plan view of a board illustrated in FIG. 7;

FIGS. 10A through 10J are cross-sectional views illustrating a method of manufacturing the electronic device module illustrated in FIG. 6A; and

FIG. 11 is a bottom perspective view schematically illustrating an electronic device module according to another exemplary embodiment in the present disclosure.

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

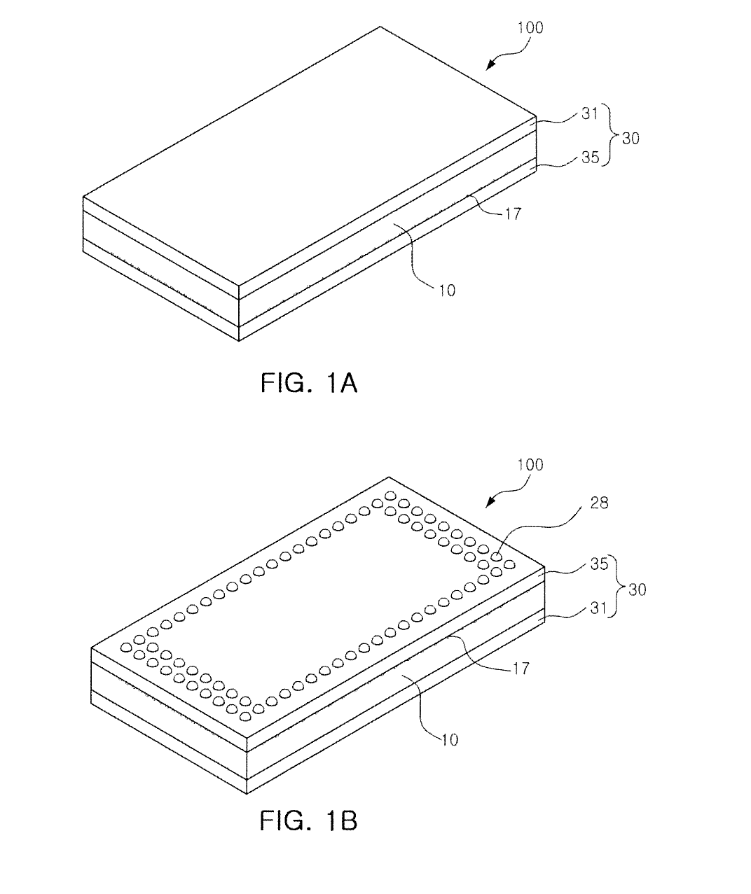

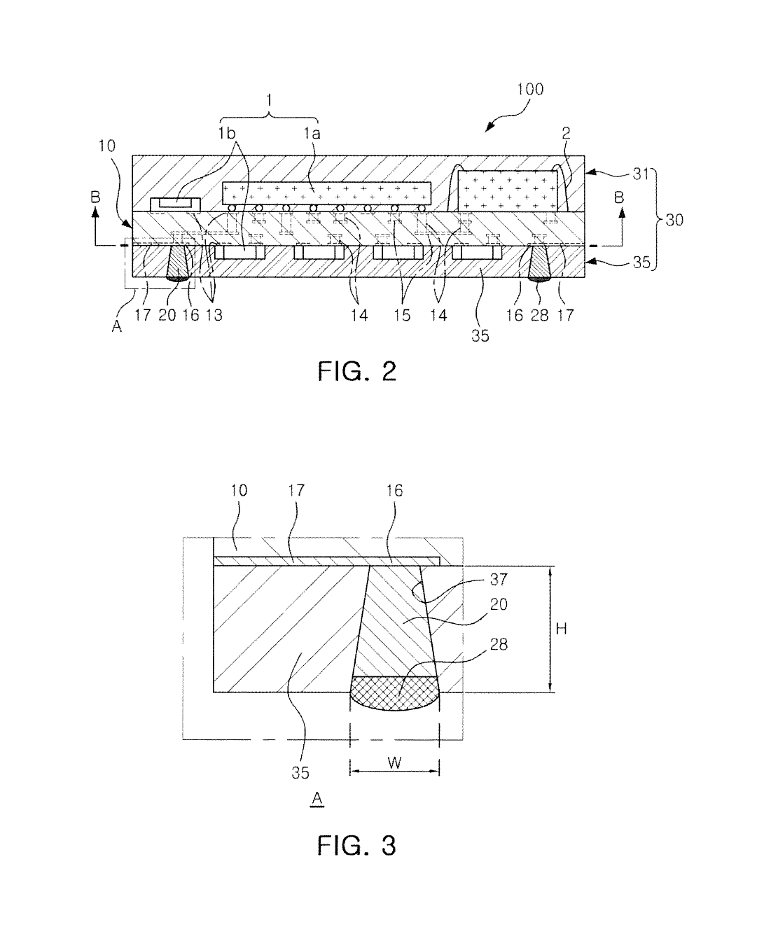

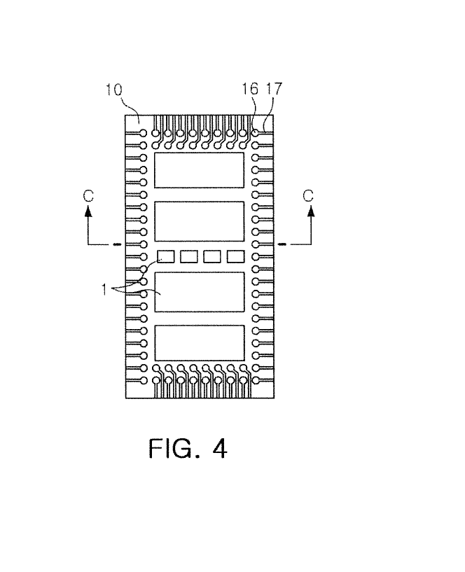

FIG. 1A is a top perspective view of an electronic device module according to an exemplary embodiment in the present disclosure; and FIG. 1B is a bottom perspective view of the electronic device module illustrated in FIG. 1A. In addition, FIG. 2 is a cross-sectional view of the electronic device module illustrated in FIG. 1A; FIG. 3 is a partially enlarged cross-sectional view of part A of FIG. 2; and FIG. 4 is a plan view of a board illustrated in FIG. 2. Here, FIG. 4 illustrates a state in which electronic devices are mounted, and FIG. 2 illustrates a cross section of the electronic device module taken along line C-C of FIG. 4.

Referring to FIGS. 1A through 4, an electronic device module 100 according to the present exemplary embodiment may include electronic devices 1, a board 10, a molded part 30, connective conductors 20, and external terminals 28.

The electronic devices 1 may include various devices such as an active device 1a and a passive device 1b and may be any electronic devices 1 that may be mounted on the board.

The electronic devices 1 may be mounted on one surface or both surfaces of a board 10 to be described below. In addition, the electronic devices 1 may be disposed in various forms on both surfaces of the board 10 depending on sizes or forms thereof and a design of the electronic device module 100.

The electronic devices 1 may be mounted in a flip-chip form on the board 10 or be electrically bonded to the board 10 through bonding wires 2.

As the board 10, various kinds of boards (for example, a ceramic board, a printed circuit board (PCB), a flexible board, and the like) well known in the art may be used. In addition, the board 10 may have one or more electronic devices 1 mounted on at least one surface thereof.

The board 10 may have a plurality of electrodes 13 and 16 formed on one surface or both surfaces thereof. Here, the electrodes may include a plurality of mounting electrodes 13 for mounting the electronic devices 1 and a plurality of external connection electrodes 16 to which the external terminals are electrically connected. The external connection electrodes 16 may be provided in order to be electrically connected to connective conductors 20 to be described below and may be connected to the external terminals 28 through the connective conductors 20.

The board 10 according to the present exemplary embodiment described above maybe a multilayer board including a plurality of layers, and circuit patterns 15 for forming electrical connection may be formed between the plurality of layers. In addition, the board 10 according to the present exemplary embodiment may include conductive vias 14 electrically connecting the electrodes 13 and 16 and the circuit patterns 15 formed in the board 10 to each other.

Meanwhile, the board 10 may have plating lines 17 formed on at least one surface thereof, wherein the plating lines 17 are used for electroplating. The plating lines 17 may be used in a process of forming connective conductors 20 to be described below by the electroplating.

The plating lines 17 may be used in order to form connective conductors 20 to be described below, which will be described below in more detail in a description for a method of manufacturing an electronic device module.

The plating lines 17 may be formed in a form of wiring patterns linearly extending from the respective external connection electrodes 16 by a predetermined distance. Here, the respective plating lines 17 may be disposed to be directed toward an outward direction of the board 10, but are not limited thereto.

The molded part 30 may include a first molded part 31 formed on an upper surface of the board 10 and a second molded part 35 formed on a lower surface of the board 10.

The molded part 30 may seal the electronic devices 1 mounted on both surfaces of the board 10. In addition, the molded part 30 may be filled between the electronic devices 1 mounted on the board 10 to prevent an electrical short-circuit from occurring between the electronic devices 1, and may fix the electronic devices 1 onto the board while enclosing outer portions of the electronic devices 1, thereby safely protecting the electronic devices 1 from external impact.

The molded part 30 according to the present exemplary embodiment may be formed of an insulating material including a resin such as an epoxy molding compound (EMC). However, the present inventive concept is not limited thereto.

The first molded part 31 according to the present exemplary embodiment maybe formed in a form in which it entirely covers one surface of the board 10. In addition, a case in which all of the electronic devices 1 are completely embedded in the first molded part 31 has been described by way of example in the present exemplary embodiment. However, the present inventive concept is not limited thereto, but may be variously applied. For example, at least one of the electronic devices 1 embedded in the first molded part 31 may be configured to be partially exposed to the exterior of the first molded part 31.

The second molded part 35 may be formed on the lower surface of the board 10 and may have one or more connective conductors 20 formed therein.

The second molded part 35 may be formed to allow all of the electronic devices 1 to be embedded therein, similar to the first molded part 31. Alternatively, the second molded part 35 may also be formed such that some of the electronic devices 1 are exposed to the exterior of the second molded part 35.

The connective conductor 20 may be disposed in a form in which the connective conductor 20 is bonded to the external connection electrode 16 of the board 10, may have one end bonded to the board 10, and may be connected to the external terminal 28. Therefore, the connective conductor 20 may be formed in the molded part 30 in a form in which the connective conductor penetrates through the molded part 30.

The connective conductor 20 may be formed of a conductive material, for example, copper, gold, silver, aluminum, or an alloy thereof.

The connective conductor 20 according to the present exemplary embodiment maybe formed of the same material as that of the electrodes 13 and 16. In detail, the connective conductor 20 may be formed of the same material as that of the external connection electrode 16 to which it is connected.

Therefore, in a case in which the external connection electrode 16 is formed of copper (Cu), the connective conductor 20 may also be formed of copper (Cu), the connective conductor 20 and the external connection electrode 16 may be formed integrally with each other using the same material.

In this case, since a separate heterogeneous metal such as nickel (Ni) or gold (Au) is not interposed between the external connection electrode 16 and the connective conductor 20, reliability in coupling between the external connection electrode 16 and the connective conductor 20 may be increased.

The connective conductor 20 according to the present exemplary embodiment maybe formed in a form similar to a conical form in which a horizontal cross-sectional area thereof becomes smaller toward one end thereof, that is, toward the board 10. However, a form of the connective conductor 20 is not limited thereto, but may be variously changed as long as a horizontal cross-sectional area of the connective conductor 20 close to the board 10 is smaller than that of the connective conductor 20 close to an outer surface of the molded part 30.

The connective conductor 20 may have the external terminal 28 bonded to the other end thereof. The external terminal 28 may electrically and physically connect the electronic device module 100 and a main board (not illustrated) on which the electronic device module 100 is mounted to each other. The external terminal 28 may be formed in a pad form, but is not limited thereto. That is, the external terminal 28 may be formed in various forms such as a bump form, a solder ball form, and the like.

The other end of the connective conductor 20 may be formed to have a concave shape toward the inside of the second molded part 35, as illustrated in FIG. 3. In addition, a portion of the external terminal 28 may be introduced into a via hole 37 to thereby be filled in a remaining space. In this case, since the portion of the external terminal 28 is inserted into the via hole 37 in a protrusion form, coupling force between the external terminal 28 and the connective conductor 20 or the molded part 30 may be increased.

However, the configuration of the present inventive concept is not limited thereto, but maybe variously modified. For example, the other end of the connective conductor 20 may protrude to be convex outwardly of the second molded part 35 or be formed in a flat shape in which it is in parallel with one surface of the board 10.

A case in which the connective conductors 20 are formed in only the second molded part 35 has been described by way of example in the present exemplary embodiment. However, the configuration of the present inventive concept is not limited thereto. That is, the connective conductors 20 may also be formed in the first molded part 31, if necessary.

The connective conductors 20 are not formed in the board 10, but may be formed in the second molded part 35 in order to connect to the board 10 and the external electrodes 28 to each other. Therefore, the connective conductor 20 may be formed at a size corresponding to that of the external terminal 28 or the external connection electrode 16 of the board 10.

In more detail, the via hole 37 according to the present exemplary embodiment may have a depth of 200 μm or more. In addition, referring to FIG. 3, a depth H of the via hole 37 may be equal to or larger than a maximum width W (or diameter) of the via hole 37.

For example, a depth H of the via hole 37 may be equal to one to two times the maximum width W of the via hole 37. That is, in a case in which the maximum width W of the via hole 37 is 200 μm, the depth H of the via hole 37 may be 200 to 400 μm. A case in which the width W of the via hole 37 is 300 μm and the depth H thereof is 500 μm has been described by way of example in the present exemplary embodiment.

Meanwhile, in a case in which a height (length) of the connective conductor 20 is smaller than the depth of the via hole 37 as in the present exemplary embodiment, an entire size of the connective conductor 20 maybe slightly smaller than that of the via hole 37.

However, the present inventive concept is not limited thereto. That is, in a case in which the connective conductor 20 is completely filled in the via hole 37, the connective conductor 20 may be formed at the same size as that of the via hole 37.

The connective conductor 20 according to the present exemplary embodiment may be formed through plating. However, as described above, the size and the length of the connective conductor 20 according to the present exemplary embodiment may be larger than those of a general conductive via formed in the board 10, such that a plating time may become very long.

To this end, the connective conductor 20 according to the present exemplary embodiment may be formed through only electroplating without performing eletroless plating. This will be described below in more detail in a description for a method of manufacturing an electronic device module.

In the electronic device module 100 according to the present exemplary embodiment described above, the electronic devices 1 may be mounted on both surfaces of the board 10. In addition, the board 10 and the external terminals 28 may be electrically connected to each other by the connective conductors 20 disposed on the lower surface of the board 10.

Therefore, a plurality of electronic devices 1 may be mounted on one board, such that a degree of integration of the electronic devices may be increased.

In addition, in the electronic device module 100 according to the present exemplary embodiment, as illustrated in FIGS. 3 and 4, the plating lines 17 may extend from the external connection electrodes 16 formed on the board 10. The plating line 17, which is a component added as the connective conductor 20 is formed in a plating scheme, maybe a component necessarily included in the electronic device module 100 in a case in which the electronic device module 100 is manufactured by a method of manufacturing an electronic device module to be described below.

Next, a method of manufacturing an electronic device module according to the present exemplary embodiment will be described.

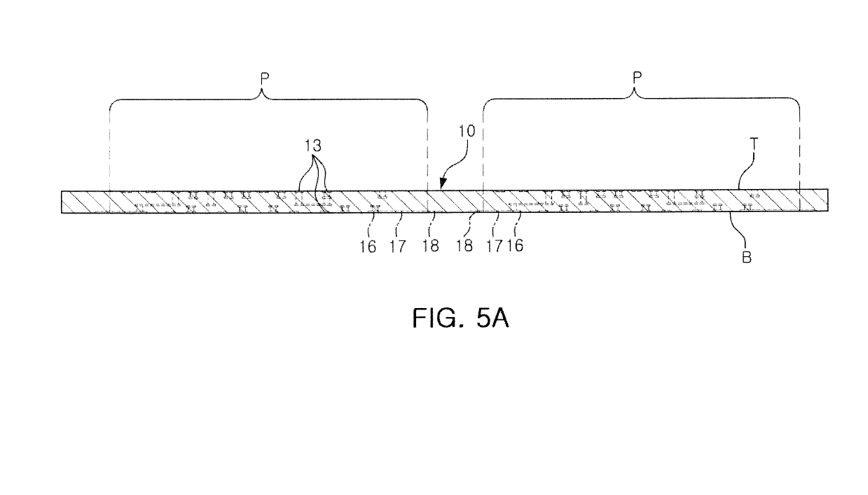

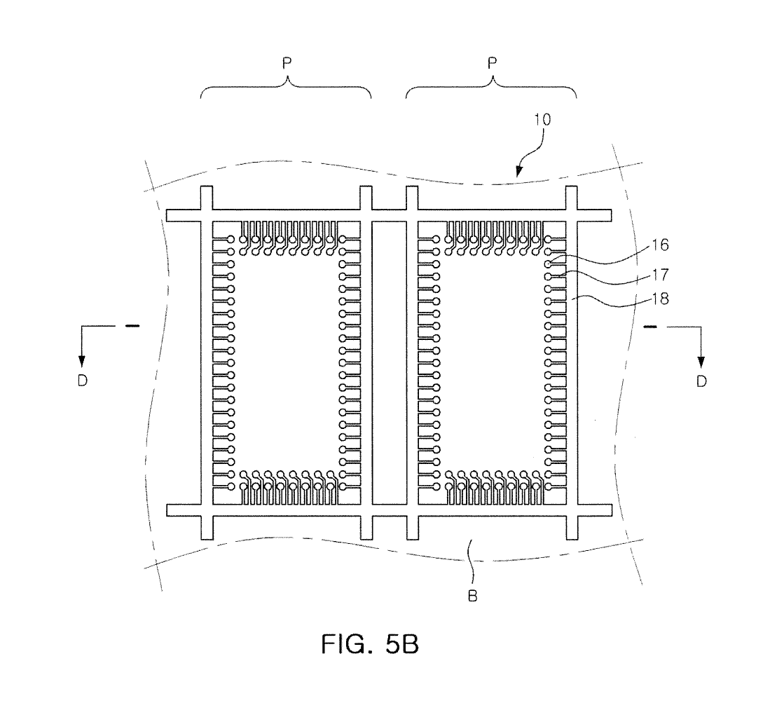

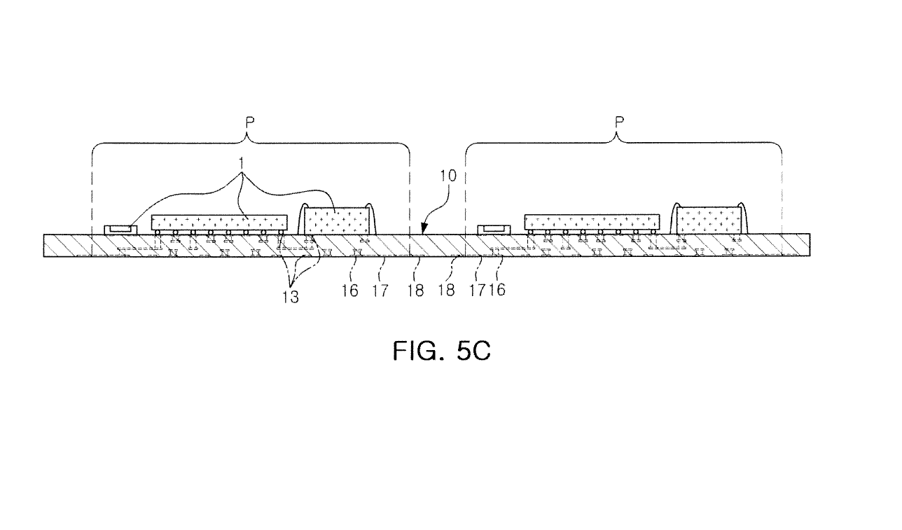

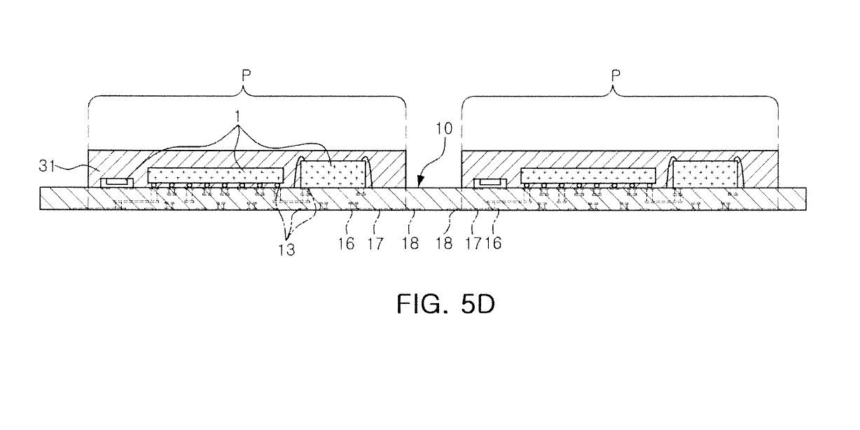

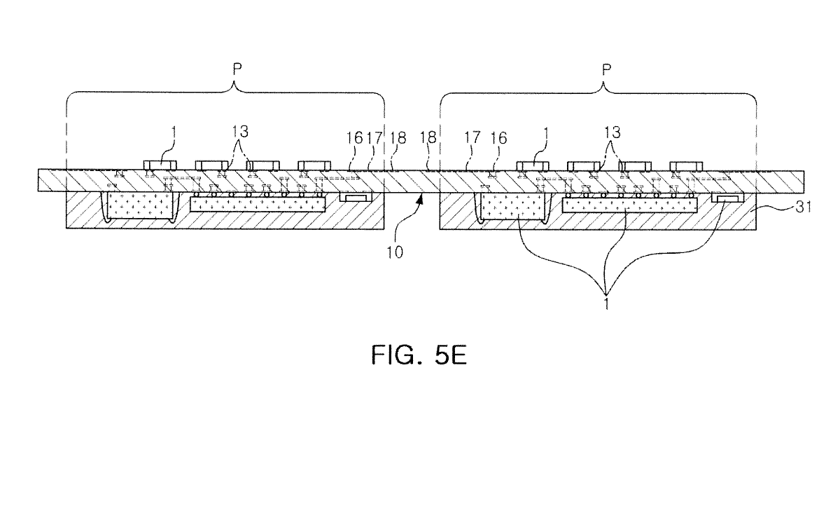

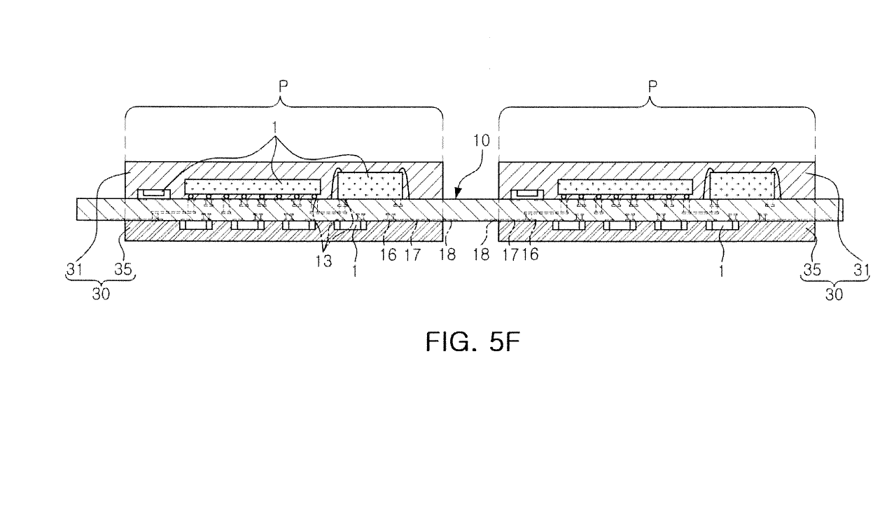

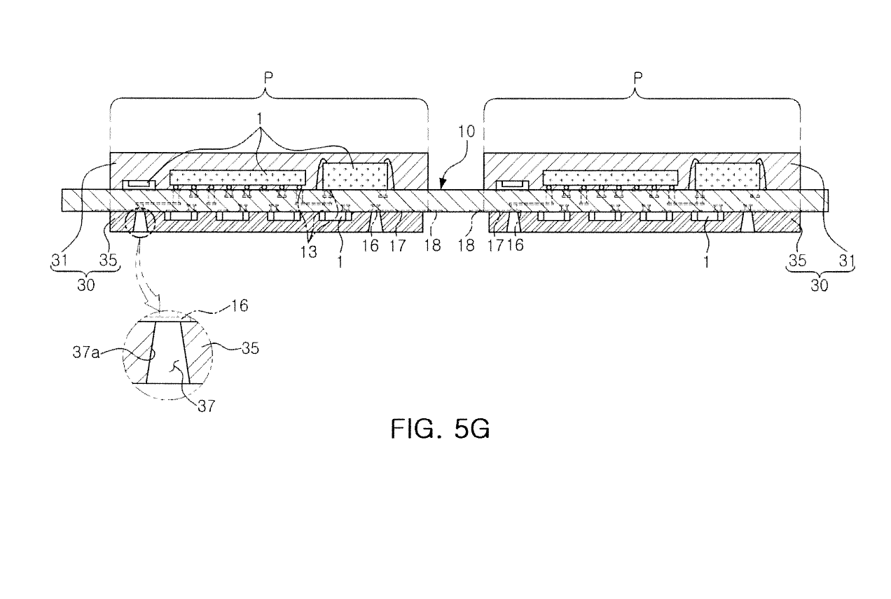

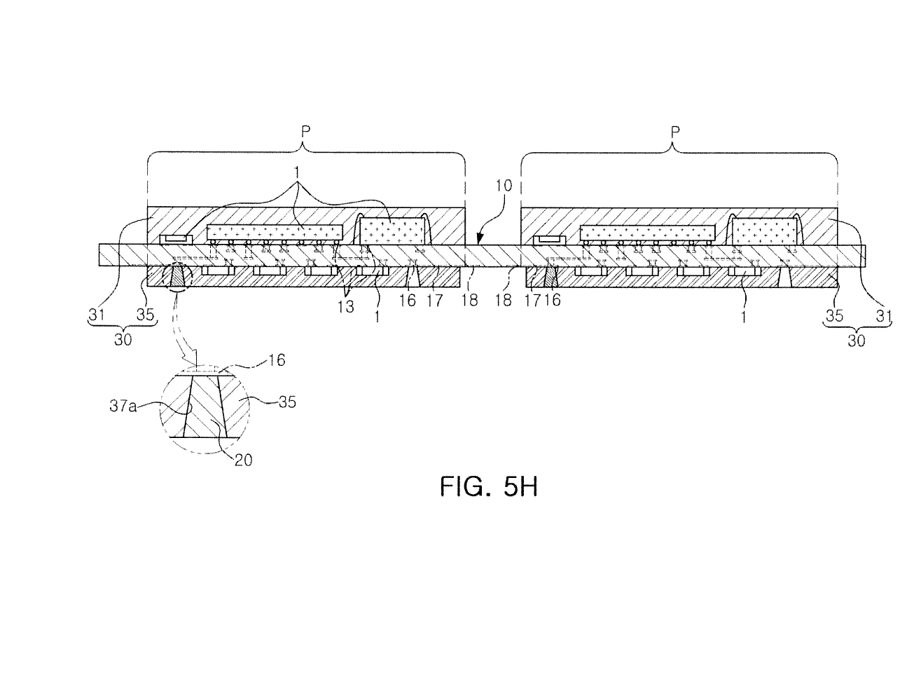

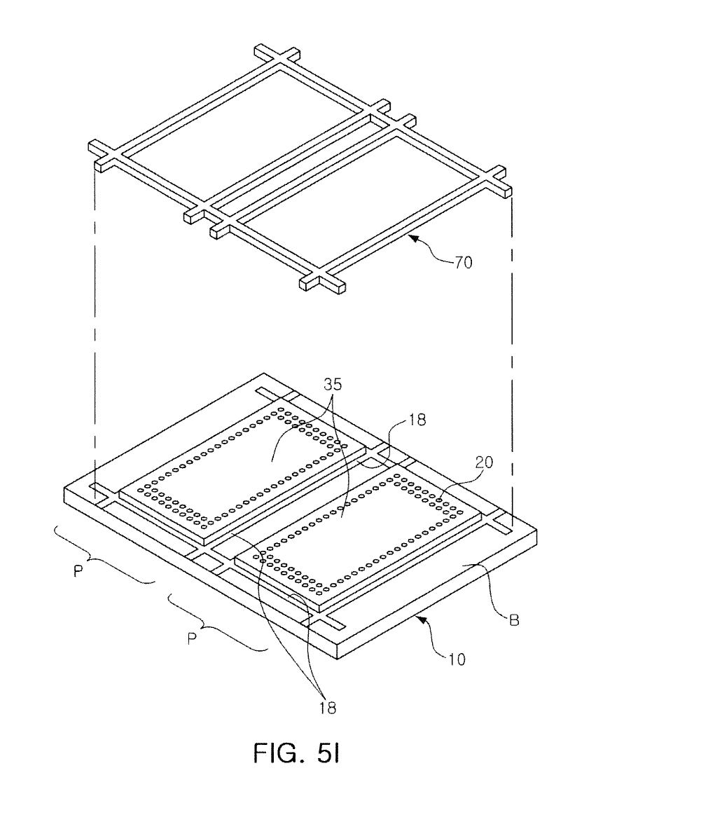

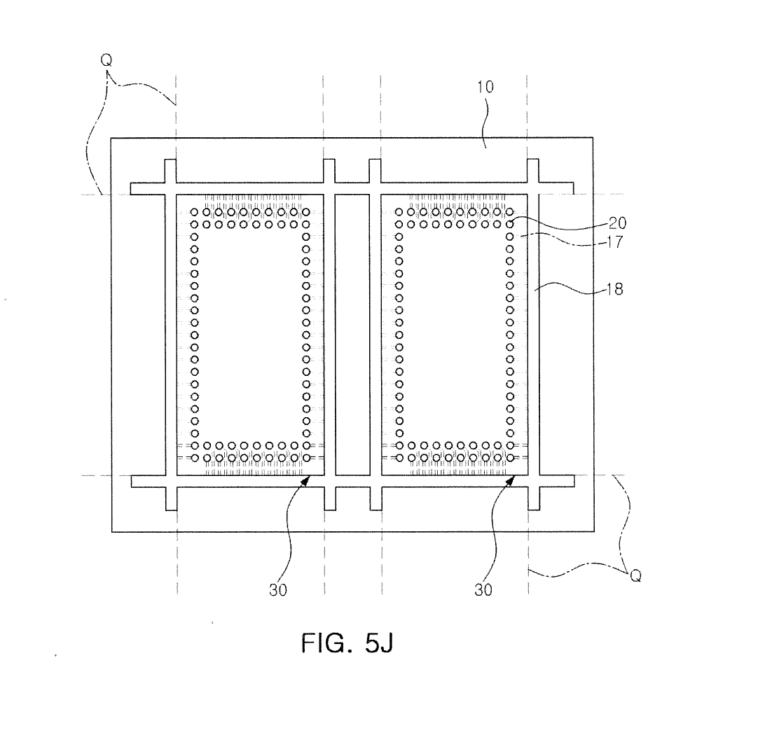

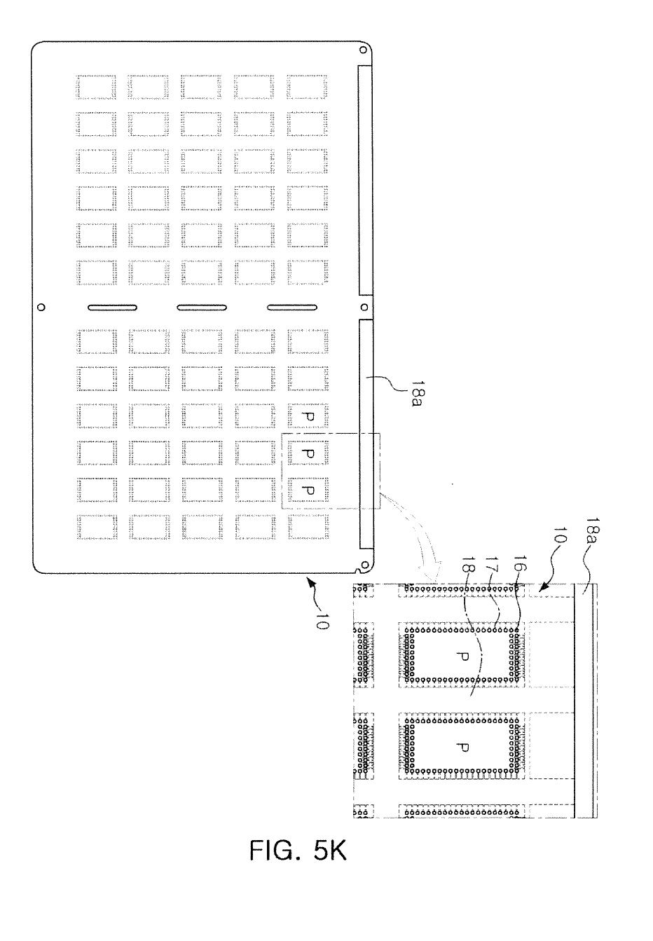

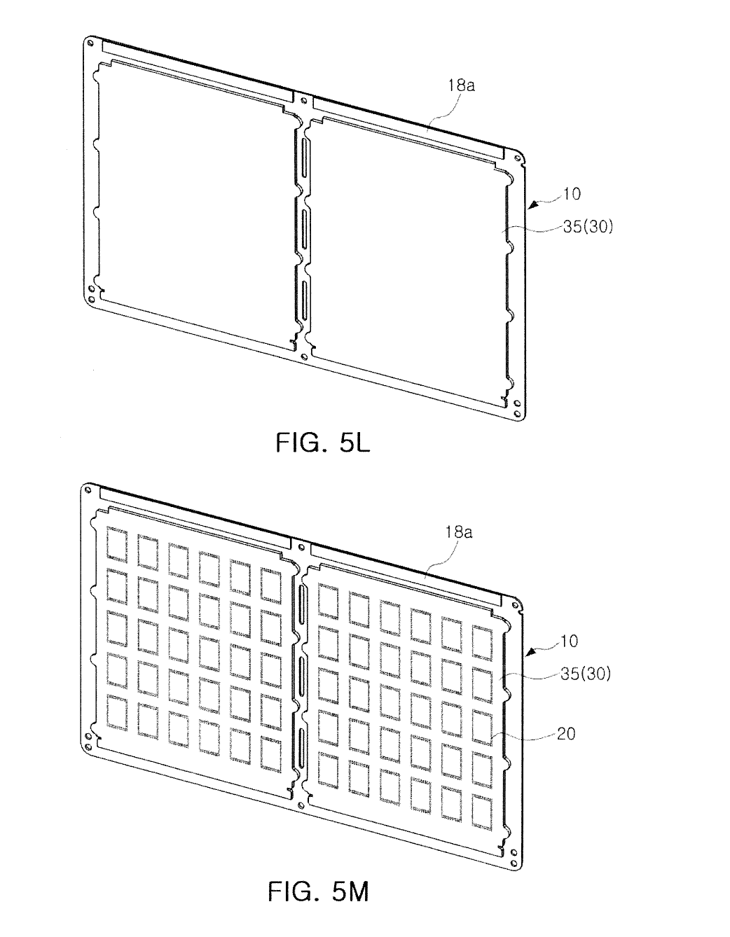

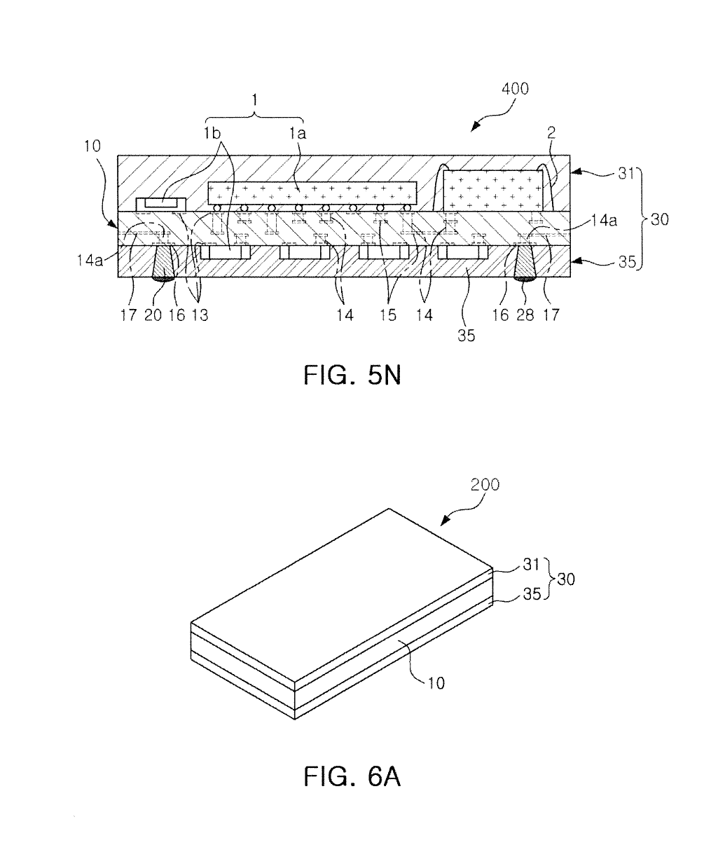

FIGS. 5A through 5J are cross-sectional views illustrating a method of manufacturing the electronic device module illustrated in FIG. 1A.

First, as illustrated in FIGS. 5A and 5B, an operation of preparing the board 10 maybe performed. As described above, the board 10 may be a multilayer board having an upper surface T and a lower surface B, and may have mounting electrodes 13 (omitted in FIG. 5B) formed on both surfaces thereof. In addition, the board 10 may have one or more external connection electrodes 16 formed on the lower surface B thereof.

In addition, the board 10 according to the present exemplary embodiment may include the plating lines 17 extending from the external connection electrodes 16. The plating lines 17 may be disposed in a form in which the plating lines extend toward an outer side of a device mounting region, as described above.

Meanwhile, the board 10 prepared in the present operation, which is a board having a plurality of same module mounting regions P repeatedly disposed therein, may have a rectangular shape or a long strip shape with a wide area. Therefore, a description will be provided below using both of a board and a board strip.

The board strip 10 may be simultaneously manufactured and form a plurality of electronic device modules, a plurality of individual module mounting regions P may be divided on the board strip 10, and electronic device modules may be manufactured for each of the plurality of individual module mounting regions P.

In this case, plating patterns 18 may be formed along the individual module mounting regions P. The plating patterns 18 may be formed along the surroundings of the individual module mounting regions P and be electrically connected to the respective plating lines 17.

The plating patterns 18 may be electrically connected to an external power source through a jig, or the like, to supply a current to the plating lines 17. However, the configuration of the present inventive concept is not limited thereto.

Then, as illustrated in FIG. 5C, an operation of mounting the electronic devices 1 on the upper surface of the board 10 may be performed. The present operation may be performed by printing solder pastes on the mounting electrodes 13 formed on the upper surface of the board 10 in a screen printing scheme, or the like, seating the electronic devices 1 on the solder pastes, and then applying heat by a reflow process to melt and harden the solder pastes.

However, the present operation is not limited thereto, but may be performed by seating the electronic devices 1 on the upper surface of the board 10 and then electrically connecting the mounting electrodes 13 formed on the board 10 and electrodes of the electronic devices 1 to each other using the bonding wires 2.

In the present operation, the same electronic devices 1 may be mounted depending on the same layout in the respective individual module mounting regions P.

Next, as illustrated in FIG. 5D, an operation of forming the first molded parts 31 on the upper surface of the board 10 may be performed.

In the present operation, the first molded parts 31 may be formed by disposing the board 10 having the electronic devices 1 mounted thereon in a mold (not illustrated) and then injecting a molding resin into the mold. Therefore, the electronic devices 1 mounted on one surface, that is, the upper surface, of the board 10 may be protected from the external environment by the first molded parts 31.

Here, the first molded parts 31 may be formed, respectively, for each of the individual module mounting regions P, as illustrated in FIG. 5D, or be formed integrally with each other to cover all of the individual module mounting regions P of the board strip 10.

Then, as illustrated in FIG. 5E, an operation of mounting the electronic devices 1 on the lower surface of the board 10 may be performed. The present operation may be performed by printing solder pastes on the mounting electrodes 13 on the lower surface of the board 10 in a screen printing scheme, or the like, seating the electronic devices 1 on the solder pastes, and applying heat to harden the solder pastes.

Next, as illustrated in FIG. 5F, an operation of forming the second molded part 35 on the lower surface of the board 10 may be performed. The present operation may also be performed by disposing the board 10 in the mold and then injecting a molding resin into the mold.

Next, as illustrated in FIG. 5G, the via holes 37 may be formed in the second molded parts 35. The via holes 37 may be formed in a laser drill scheme.

The external connection electrodes 16 of the board 10 may be exposed externally through the via holes 37. The via hole 37 may generally have a conical form in which a horizontal cross-sectional area thereof becomes smaller toward the board 10. However, the present inventive concept is not limited thereto.

Meanwhile, the via hole 37 according to the present exemplary embodiment does not have a through-hole form, but may be a blind via hole of which one end is closed by the board 10.

In addition, as described above, the via hole 37 according to the present exemplary embodiment may be formed at a size corresponding to that of the external terminal 28 or the external connection electrode 16 of the board 10.

In more detail, the via hole 37 according to the present exemplary embodiment may have a depth of 200 μm or more. This depth has been derived in consideration of a mounting height of the electronic devices 1 embedded in the second molded part 35.

Therefore, in a case in which the mounting height of the electronic devices 1 becomes larger or smaller, a thickness of the second molded part 35 sealing the electronic devices 1 may become larger or smaller, such that a depth of the via hole 37 penetrating through the second molded part 35 maybe changed to correspond to the thickness of the second molded part 35.

In addition, a depth of the via hole 37 may be equal to one to two times a maximum width (or a maximum diameter) of the via hole 37.

For example, the via hole 37 according to the present exemplary embodiment may have a maximum diameter of 300 μm and a depth of 500 μm. However, the configuration of the present inventive concept is not limited thereto.

Next, as illustrated in FIGS. 5H and 5I, the connective conductors 20 may be formed in the via holes 37. In a case in which the connective conductor 20 is formed of copper (Cu), copper plating may be performed. In addition, the plating process may be configured of only electroplating.

In more detail, as illustrated in FIG. 5I, a metal frame 70 may be first seated on the board 10 to contact the plating patterns 18. Then, when a current is applied to the metal frame 70, the current may be applied to the external connection electrodes 16 (See FIG. 5H) through the plating patterns 18 that the metal frame 70 contacts and the plating lines 17, such that plating is performed on the external connection electrodes 16.

Meanwhile, although a case in which the metal frame 70 is formed in a form in which flat metal plates having a rod shape are coupled to each other has been illustrated in FIG. 5I, the configuration of the present inventive concept is not limited thereto, but may be variously modified, if necessary. For example, the metal frame may have a mesh shape or a lattice shape.

In the plating process according to the present exemplary embodiment, conductive materials may be grown from the external connection electrodes 16. Therefore, the conductive materials may be sequentially filled in the via holes 37 to thereby be finally formed as the connective conductors 20.

As described above, the size of the via hole 37 according to the present exemplary embodiment may be relatively larger than that of the conductive via formed in the board 10. Therefore, when the electroplating is performed after the electroless plating is performed, a conductor may be grown from sidewalls of the via hole 37 toward the center thereof. Since a growth speed of the conductor grown from the sidewalls of the via hole 37 is faster than that of a conductor grown from the bottom (that is, the external connection terminal) of the via hole 37, a void may be easily formed in the connective conductor 20.

In addition, since a size of the via hole 37 is large, when an inner portion of the via hole 37 is plated by the electroless plating, a time required for performing the plating process may be significantly increased, such that a yield may be decreased.

Therefore, in the method of manufacturing an electronic device module according to the present exemplary embodiment, the connective conductors 20 may be formed by only the electroplating.

In addition, as described above, the molded part 30 according to the present exemplary embodiment may be formed of the epoxy mold compound (EMC). Generally, it has been known that it is not easy to perform plating on a surface of the EMC, which is a thermosetting resin, that is, to bond a metal to the surface of the EMC.

Therefore, in the method of manufacturing an electronic device module according to the present exemplary embodiment, a mechanical interlocking, hooking, and anchoring theory or an anchoring effect may be used in order to plate a conductor on the surface of the EMC. The mechanical interlocking, hooking, and anchoring theory may mean a theory in which an adhesive permeates into an irregular structure (ruggedness) of a surface of a material to be adhered to thereby be bonded thereto by mechanical engagement.

That is, in the method of manufacturing an electronic device module according to the present exemplary embodiment, a method of forming an inner surface 37a (See FIG. 5H) of the via hole 37 formed of the EMC as roughly as possible and coupling the plating material to the inner surface 37a of the via hole 37 by the anchoring effect in the plating process may be used.

To this end, in the present exemplary embodiment, a surface roughness of the inner surface of the via hole 37 may be increased as much as possible in a process of forming the via hole 37 using laser, thereby forming an irregular and rough surface structure. Here, the surface roughness may be increased by adjusting a kind of laser, a size of a spot of the laser, power of the laser.

Therefore, even though the molded part 30 is formed of the EMC, heterogeneous interfaces of the connective conductor 20 and the inner surface of the via hole 37 maybe easily bonded to each other.

Meanwhile, various modifications may be made in order to increase a coupling force between the connective conductor 20 and the molded part 30. For example, substantial copper plating may be performed after a catalyst metal such as gold, platinum, palladium, or the like, is disposed in a plating target region.

In addition, in order to significantly decrease an influence of impact generated in the external connection electrode 16 due to laser irradiation, a surface of the external connection electrode 16 exposed into the via hole 37 may be partially etched.

Finally, an operation of cutting the strip board 10 on which the molded part 30 is formed to form individual electronic device modules 100 may be performed.

This operation may be performed by cutting the molded part 30 and the board 10 along cut lines Q illustrated in FIG. 5J.

Therefore, the plating patterns 18 formed in the board strip 10 may be removed, such that only the plating lines 17 may remain in the board 10. In addition, distal ends of the plating lines 17 may be exposed to the exterior of the molded part 30 through cut surfaces of the board strip 10.

Meanwhile, although the plating lines 17 are not required in operating the electronic device module, they may necessarily remain since the connective conductors 20 are formed in the molded part 30 by the plating process. Therefore, it may be confirmed through the plating lines 17 remaining on the board 10 that the connective conductors 20 have been formed in the plating scheme in the electronic device module according to the present exemplary embodiment.

Meanwhile, although not illustrated, an operation of forming the external terminals 28 (See FIG. 3) at distal ends of the connective conductors 20 may be performed before or after the operation of cutting the board strip 10. Here, the external terminals 28 may be formed in various forms such as a bump form, a solder ball form, a pad form, and the like, and be omitted, if necessary.

The electronic device module 100 according to the present exemplary embodiment illustrated in FIG. 1A may be completed through the above-mentioned processes.

Meanwhile, the method of manufacturing an electronic device module according to the present disclosure is not limited to the above-mentioned exemplary embodiment, but may be variously modified.

FIGS. 5K through 5N are views illustrating a method of manufacturing an electronic device module according to another exemplary embodiment in the present disclosure.

First, referring to FIG. 5K, in the method of manufacturing an electronic device module according to the present exemplary embodiment, the board 10 may be prepared. The board 10 prepared in the present operation, which is a board 10 having a plurality of same mounting regions P repeatedly disposed therein, may be a board 10 having a rectangular shape with a wide area.

In addition, in the board 10 according to the present exemplary embodiment, for each of individual module mounting regions P, the external connection electrodes 16 maybe exposed externally, and the plating lines 17 and the plating patterns 18 are not formed outside the board, but may be formed inside the board 10.

In addition, plating pads 18a may be formed on one side of the board 10. The plating pads 18a may be electrically connected to the plating patterns 18 of the board 10 and be connected to an external conductive member applying a current to the board in a plating process.

Therefore, the plating patterns 18 and the plating pads 18a may be electrically connected to each other by interlayer vias (not illustrated). In addition, the external connection electrodes 16 and the plating lines 17 may be electrically connected to each other by interlayer vias 14a (See FIG. 5N).

In addition, the plating pattern 18 may be formed as one line between two individual module mounting regions P disposed adjacently to each other. That is, all of the plating lines 17 of the two individual module mounting regions P may be electrically connected to one plating pattern 18.

Then, as illustrated in FIG. 5L, the electronic devices may be formed on the board 10, and the molded part 30 maybe formed. This operation may be performed by mounting the electronic devices 1 (See FIG. 5N) on one surface of the board 10, forming the first molded parts 31 (See FIG. 5N), mounting the electronic devices 1 (See FIG. 5N) on the other surface of the board 10, and then forming the second molded parts 35 (See FIG. 5N), similar to the above-mentioned exemplary embodiment.

However, the present inventive concept is not limited thereto. That is, the first and second molded parts 31 and 35 may also be simultaneously formed on both surfaces of the board 10, after all of the electronic devices 1 may be mounted on both surfaces of the board 10.

In addition, although the second molded parts 35 may be formed for each of the individual module mounting regions P in the present exemplary embodiment, similar to the above-mentioned exemplary embodiment, they may also be formed integrally with each other to cover all of the individual module mounting regions of the board 10, as illustrated in FIG. 5L. The reason is that a current may be applied to the external connection electrodes 16 in the plating process even though the second molded parts 35 are formed integrally with each other since the plating lines 17 and the plating patterns 18 according to the present exemplary embodiment are formed in the board 10.

Then, as illustrated in FIG. 5M, the via holes may be formed in the second molded part 35, and the connective conductors 20 may be formed through the electroplating. Then, the external terminals 28 (See FIG. 5N) may be formed. Since the present operations may be performed as in the above-mentioned exemplary embodiment, a detailed description therefor will be omitted.

Meanwhile, in the present operation, the electroplating may be performed by electrically connecting the plating pads 18a of the board 10 to the external power source. The plating pads 18a may be connected to a jig, a conductive member having a tongs shape, a conductive wire, or the like, to thereby be electrically connected to the external power source, but is not limited thereto.

A current applied to the plating pads 18a may be supplied to the external connection electrodes 16 through the plating patterns 18, the plating lines 17, and the interlayer vias 14a formed in the board 10. Therefore, the connective conductors 20 may be formed on the external connection electrodes 16 through the electroplating.

Finally, the board 10 on which the molded part 30 is formed may be cut to form an electronic device module 400 illustrated in FIG. 5N.

This operation may be performed by cutting the molded part 30 and the board 10 along outside lines of the plating patterns 18 illustrated in FIG. 5K.

Therefore, the plating patterns 18 formed in the board 10 may be removed, such that only the plating lines 17 may remain on the board 10. In addition, the plating lines 17 may have distal ends exposed to the exterior of the board 10 through cut surfaces of the board 10 and be electrically separated from each other.

In the electronic device module 100 or 400 according to the present exemplary embodiment as described above, the electronic devices 1 may be mounted on both surfaces of the board 10 and be sealed by the molded part 30. Therefore, many devices may be mounted in one electronic device module 100 and be easily protected from the external environment.

In addition, the connective conductors 20 may be formed in the molded part 30 in the plating scheme and be then connected to the external terminals 28. Therefore, conductor paths and circuit wirings connecting the board 10 and the external power source to each other may be very easily formed even in a double-sided molding structure or a package stack structure, such that the electronic device module may be easily manufactured.

Meanwhile, the present inventive concept is not limited to the above-mentioned exemplary embodiments, but may be variously modified.

Electronic device modules according to exemplary embodiments to be described below may be configured similarly to the electronic device module according to the above-mentioned exemplary embodiment except for configurations of a molded part and a plating line. Therefore, a detailed description for components that are the same as or similar to those of the electronic device module according to the above-mentioned exemplary embodiment will be omitted, and components that are different from those of the electronic device module according to the above-mentioned exemplary embodiment will be mainly described.

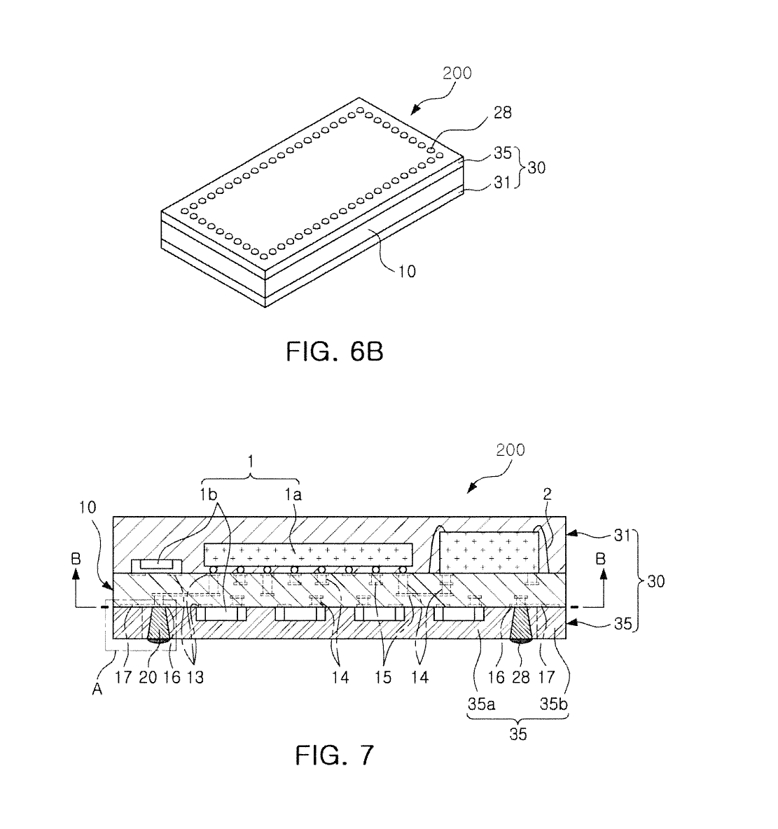

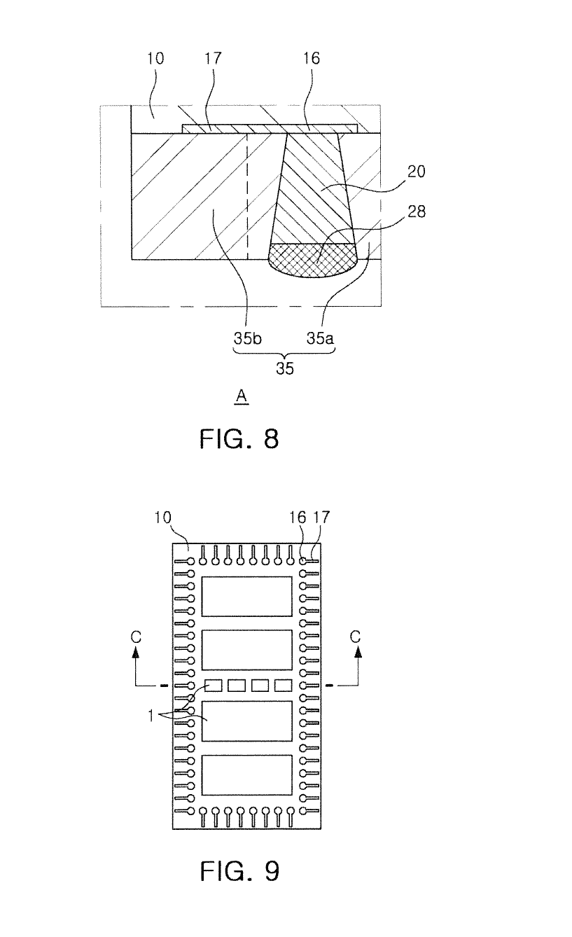

FIG. 6A is a perspective view schematically illustrating an electronic device module according to another exemplary embodiment in the present disclosure; and FIG. 62 is a bottom perspective view of the electronic device module illustrated in FIG. 6A. In addition, FIG. 7 is a cross-sectional view of the electronic device module illustrated in FIG. 6A; FIG. 8 is a partially enlarged cross-sectional view of part A of FIG. 7; and FIG. 9 is a plan view of aboard illustrated in FIG. 8. Here, FIG. 9 illustrates a state in which electronic devices are mounted for convenience of explanation, and FIG. 8 illustrates a cross section taken along line C-C of FIG. 9.

Referring to FIGS. 6A through 9, an electronic device module 200 according to the present exemplary embodiment may include electronic devices 1, a board 10, a molded part 30, connective conductors 20, and external terminals 28.

The electronic devices 1 may be the same as those of the electronic device module according to the above-mentioned exemplary embodiment. Therefore, a detailed description for the electronic devices 1 will be omitted.

The board 10 may be generally similar to that of the electronic device module according to the above-mentioned exemplary embodiment except for a configuration of a plating line 17.

In the board 10 according to the present exemplary embodiment, one or more plating lines 17 may be connected to respective external connection electrodes 16.

The plating lines 17 may be used in order to form connective conductors 20 to be described below, which will be described below in more detail in a description for a method of manufacturing an electronic device module.

The plating lines 17 may be formed in a form of wiring patterns linearly extending from the respective external connection electrodes by a predetermined distance. Here, the respective plating lines 17 may be disposed to be directed toward an outward direction of the board 10, but are not limited thereto.

In addition, the plating lines 17 according to the present exemplary embodiment may be formed within the board 10, and are not exposed to side surfaces of the board 10, that is, the exterior of the electronic device module 200.

In a case in which the plating lines 17 are exposed to the exterior of the board 10, an electromagnetic wave may be introduced or leaked through the exposed plating lines 17. In addition, an electric field may be concentrated along exposed portions.

Therefore, in the electronic device module 200 according to the present exemplary embodiment, the plating lines 17 may be formed only in the board 10 and be completely covered by the molded part 30. Therefore, the plating lines 17 may not be exposed externally.

This configuration may be obtained by a method of manufacturing an electronic device module according to another exemplary embodiment in the present disclosure, which will be described below.

The molded part 30 may include a first molded part 31 formed on an upper surface of the board 10 and a second molded part 35 formed on a lower surface of the board 10.

The molded part 30 according to the present exemplary embodiment may be formed of an insulating material including a resin such as an epoxy molding compound (EMC). However, the present inventive concept is not limited thereto.

The first molded part 31 may be formed in a form in which it entirely covers one surface of the board 10.

The second molded part 35 may be formed on the lower surface of the board 10 and may have the connective conductors 20 formed therein.

In addition, the second molded part 35 according to the present exemplary embodiment may be divided into an inner molded part 35a and an outer molded part 35b.

The inner molded part 35a may allow the electronic devices 1 mounted on the lower surface of the board 10 and the connective conductors 20 to be embedded therein. In addition, the outer molded part 35b may be disposed at an outer side of the inner molding part 35a.

The outer molded part 35b may be provided in order to allow the above-mentioned plating lines 17 to be embedded therein. Therefore, the outer molded part 35b may be formed at a width at which it completely covers the plating lines 17.

The connective conductor 20 may also be the same as those of the electronic device module according to the above-mentioned exemplary embodiment. Therefore, a detailed description for the connective conductors 20 will be omitted.

In the electronic device module 200 according to the present exemplary embodiment configured as described above, the plating lines 17 are not exposed to the exterior of the electronic device module 200, but may be formed in the electronic device module 200. This structure may be obtained by the method of manufacturing an electronic device module according to the present exemplary embodiment.

Since the plating lines 17 are not exposed to the exterior of the electronic device module 200, the introduction/leakage of the electromagnetic wave through the exposed plating lines 17 or the concentration of the electric field along the exposed portion may be prevented.

Next, a method of manufacturing an electronic device module according to the present exemplary embodiment will be described.

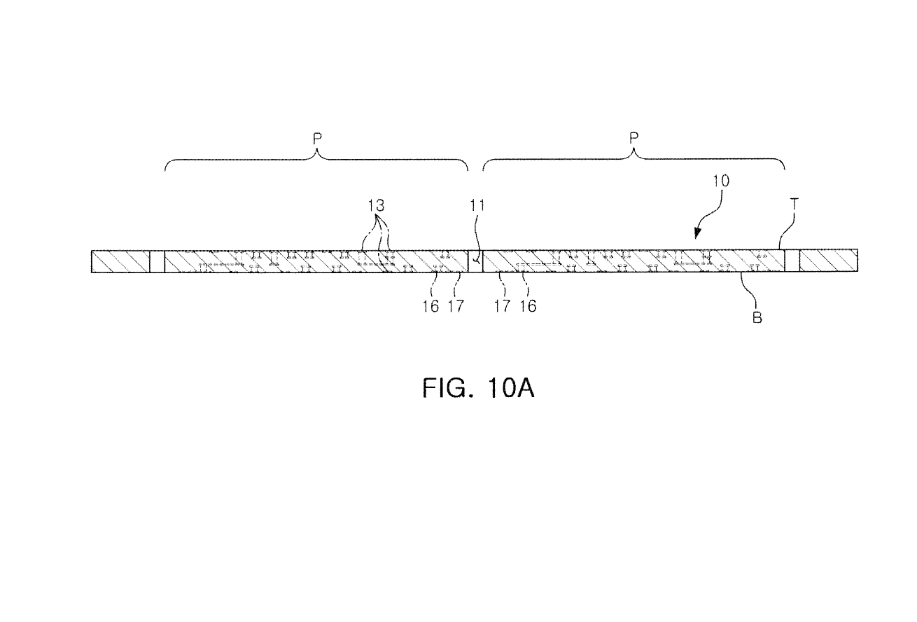

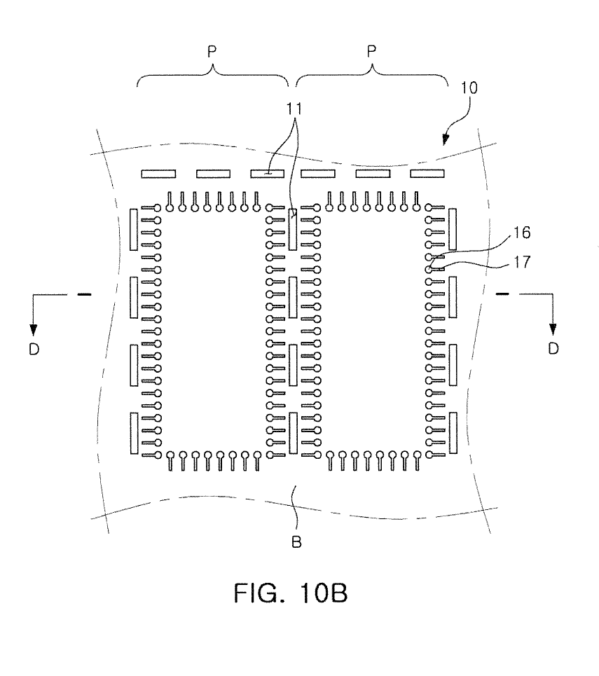

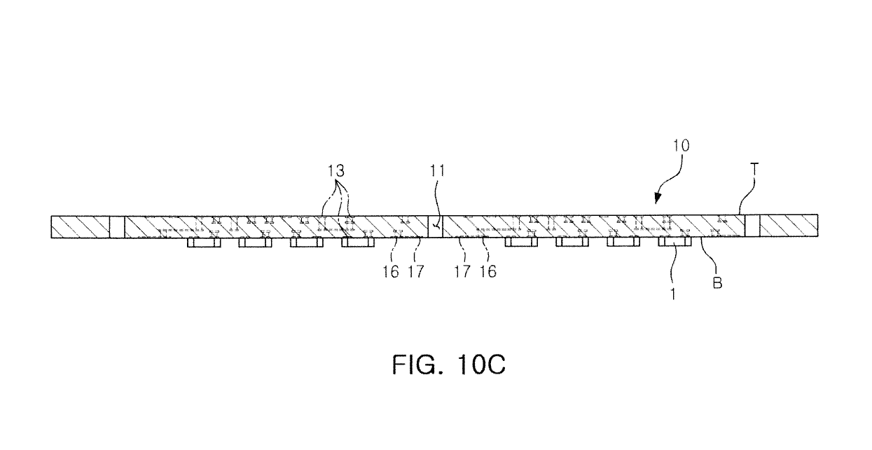

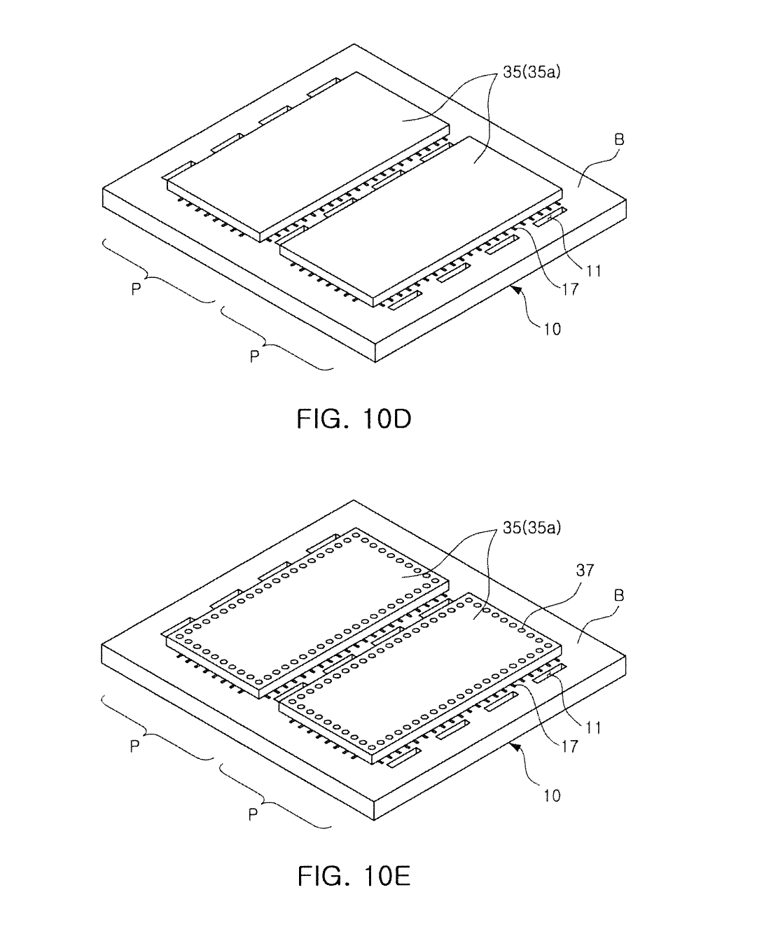

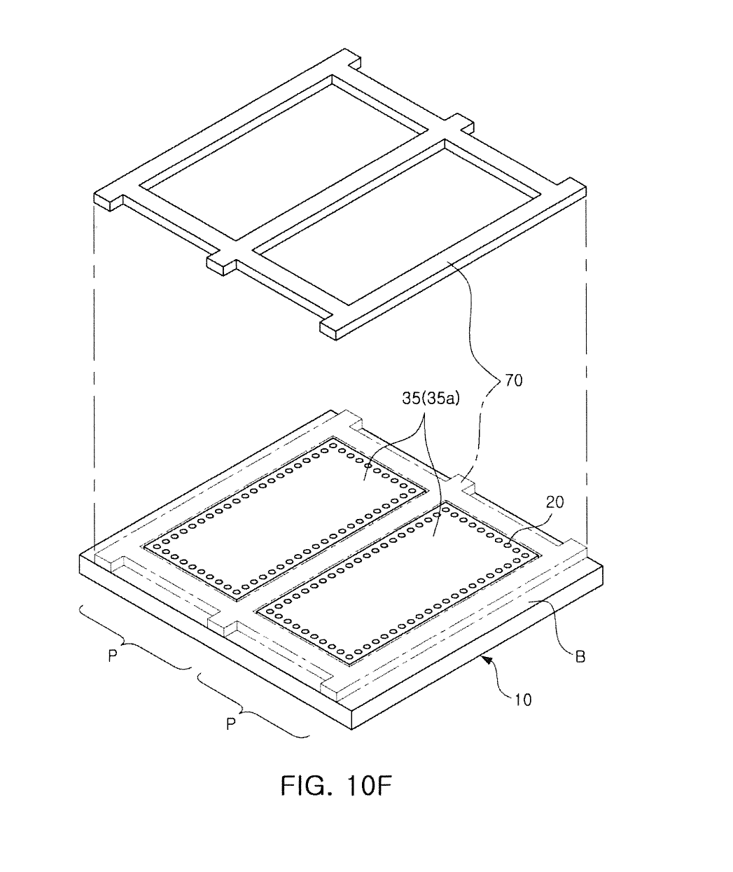

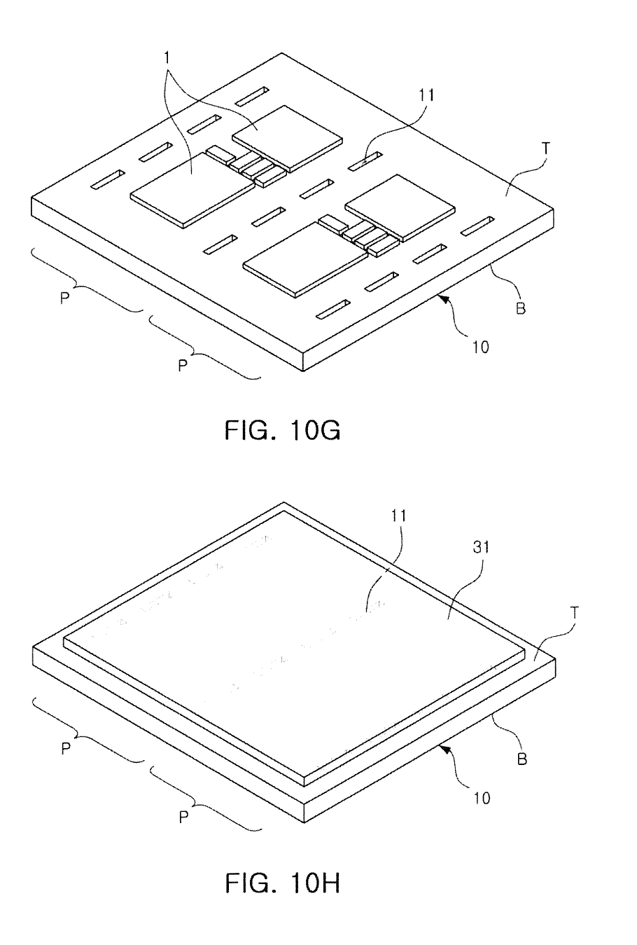

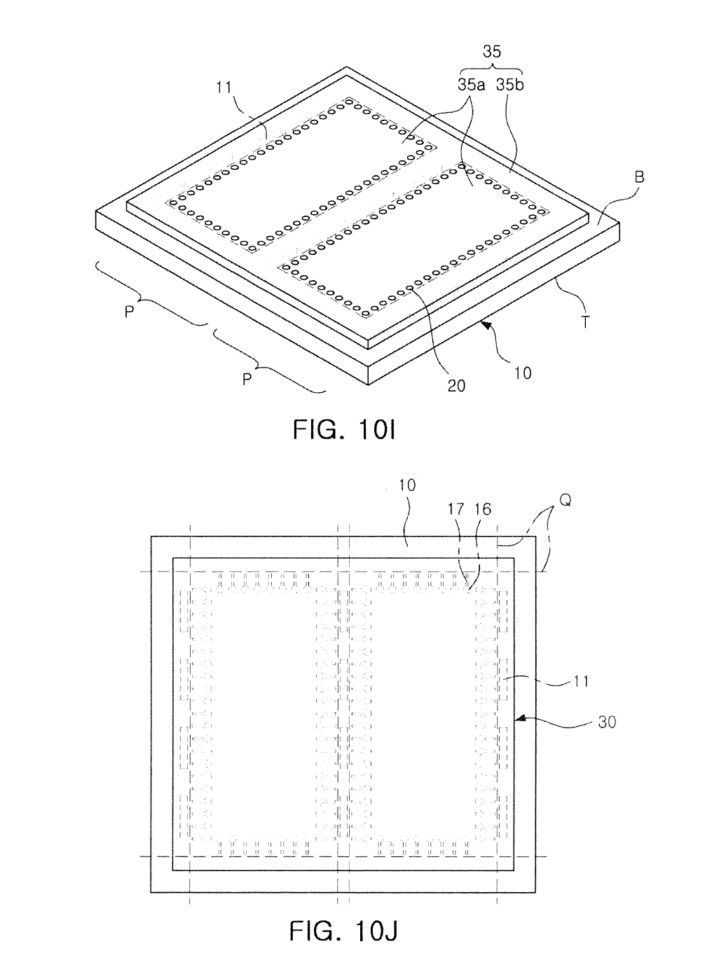

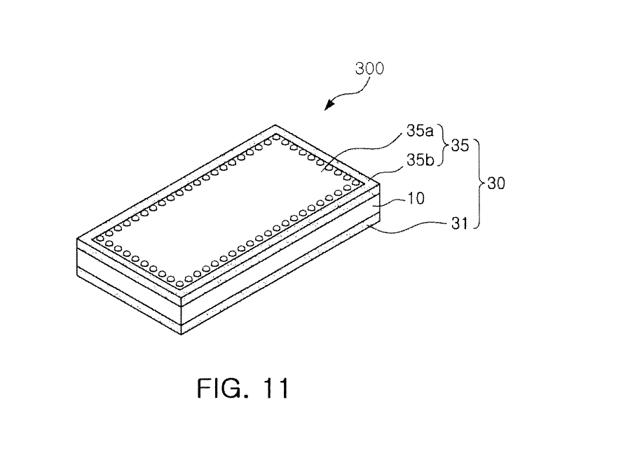

FIGS. 10A through 10J are cross-sectional views illustrating a method of manufacturing the electronic device module illustrated in FIG. 6A.

First, as illustrated in FIGS. 10A and 10B, an operation of preparing the board 10 may be performed. As described above, the board 10 may be a multilayer board, and may have the mounting electrodes 13 (omitted in FIG. 10B) formed on both surfaces thereof. In addition, the board 10 may have the external connection electrodes 16 formed on the lower surface B thereof.

In addition, the board 10 according to the present exemplary embodiment may include the plating lines 17 extended from the external connection electrodes 16. The plating lines 17 may be disposed in a form in which they are extended toward an outer side of the board 10, as described above.

Meanwhile, the board 10 prepared in the present operation, which is a board having a plurality of same mounting regions P repeatedly disposed therein, may have a rectangular shape or a long strip shape with a wide area.

The board 10 may be to simultaneously manufacture and form a plurality of electronic device modules, a plurality of individual module mounting regions P may be divided on the board 10, and electronic device modules maybe manufactured for each of the plurality of individual module mounting regions P.

In addition, the board strip 10 may have one or more through-holes 11 formed therein. The through-holes 11 may be formed in a space between the individual module mounting regions P and be formed along boundaries between the individual module mounting regions P.

The through-holes 11 may be used as paths through which a molding resin moves in a process of forming a molded part 30 to be described below. This will be described below.

Then, as illustrated in FIG. 10C, an operation of mounting the electronic devices 1 on one surface, that is, the lower surface, of the board 10 may be performed. The present operation may be performed by printing solder pastes on the mounting electrodes 13 formed on the lower surface B of the board 10 in a screen printing scheme, or the like, seating the electronic devices 1 on the solder pastes, and then applying heat by a reflow process to melt and harden the solder pastes.

However, the present operation is not limited thereto, but maybe performed by seating the electronic devices 1 on the lower surface B of the board 10 and then electrically connecting the mounting electrodes 13 formed on the board 10 and electrodes of the electronic devices 1 to each other using the bonding wires 2.

In the present operation, the same electronic devices 1 may be mounted in the respective individual module mounting regions P having the same layout.

Next, as illustrated in FIG. 10D, an operation of forming parts of the second molded part 35, that is, the inner molded parts 35a on one surface of the board 10 may be performed.

In the present operation, the inner molded parts 35a may be formed by disposing the board 10 having the electronic devices 1 mounted thereon in a mold (not illustrated) and then injecting a molding resin into the mold. The inner molded part may be formed, such that the electronic devices 1 mounted on the lower surface B of the board 10 may be protected from the external environment by the inner molded part 35a.

Meanwhile, the second molded parts 35 according to the present exemplary embodiment may be formed for each of the individual module mounting regions P, and be formed so that all of the through-holes are exposed. Therefore, the inner molded parts 35a may be formed in inner regions partitioned by the through-holes 11.

In addition, the inner molded parts 35a formed in the present operation may be parts of the second molded parts 35 rather than the entirety of the second molded parts 35, and the outer molded parts, which are the other parts of the second molded parts 35, may be formed in a process of forming a first molded part 31 to be described below.

In addition, the inner molded parts 35a formed in the present operation may have a size and a shape enough for the plating lines 17 to be exposed to the exterior of the inner molded parts 35a. Therefore, after the inner molded parts 35a are formed in the present operation, the plating lines 17 may be exposed in a form in which all of distal ends thereof protrude to the exterior of the inner molded parts 35a.

Next, as illustrated in FIG. 10E, the via holes 37 may be formed in the inner molded parts 35a. The via holes 37 may be formed using a laser drill.

The external connection electrodes 16 of the board 10 may be exposed externally through the via holes 37. Meanwhile, as illustrated in FIG. 8, the via hole 37 may generally have a conical form in which a horizontal cross-sectional area thereof becomes smaller toward the board 10. However, the present inventive concept is not limited thereto.

Then, the connective conductors 20 may be formed in the via holes 37 in a plating scheme.

In a case in which the connective conductor 20 is formed of copper (Cu), copper plating may be performed. Here, the plating process may be implemented with only electroplating.

In more detail, as illustrated in FIG. 10F, a metal frame 70 may be first seated on the board 10 to contact the plating lines 17 (See FIG. 10E). Then, when a current is applied to the metal frame 70, the current may be applied to the external connection electrodes 16 (See FIG. 10B) through the plating lines 17 electrically connected to the metal frame 70, such that plating is performed on the external connection electrodes 16.

The plating process maybe performed while filling conductive materials in the via holes 37 sequentially from the external connection electrodes 16, thereby finally forming the connective conductors 20.

Then, as illustrated in FIG. 10G, an operation of mounting the electronic devices 1 on the upper surface T of the board 10 may be performed. The present operation may be performed by printing solder pastes on the mounting electrodes 13 (See FIG. 10A) in a screen printing scheme, or the like, seating the electronic devices 1 on the solder pastes, and then applying heat by a reflow process to melt and harden the solder pastes.

Next, as illustrated in FIG. 10H, an operation of forming the first molded part 31 on the upper surface T of the board 10 may be performed. The present operation may be performed by disposing the board 10 in the mold and then injecting a molding resin into the mold, similar to a case illustrated in FIG. 10D.

In this process, the molding resin injected into the mold may be introduced into the lower surface B of the board 10 through the through-holes 11 as well as into the upper surface T of the board 10.

Therefore, the molding resin may form the first molded part 31 on the upper surface T of the board 10 and at the same time, be filled along circumferences of the inner molded parts 35a formed on the lower surface B of the board 10, as illustrated in FIG. 10I, to complete the outer molded part 35b.

In this process, the additionally formed outer molded part 35b may be formed while covering the plating lines 17 (See FIG. 10E) formed in the board 10. Therefore, the plating lines 17 exposed on the lower surface of the board 10 may be completely embedded by the additionally formed outer molded part 35b.

Finally, an operation of cutting the strip board 10 on which the molded part 30 is formed to form individual electronic device modules 200 may be performed.

This operation may be performed by cutting the molded part 30 and the board 10 along cut lines Q illustrated in FIG. 10J.

Here, the cut lines Q may be defined so that the plating lines 17 according to the present exemplary embodiment are not exposed to cut surfaces. For example, the cut lines Q may be formed between the through-holes 11 and the plating lines 17 or be formed to be partially shared with inner walls of the through-holes 11.

Therefore, the electronic device modules may be separated from each other, respectively, in a state in which the plating lines 17 are completely embedded in the molded part 30 without being exposed externally.

Meanwhile, although not illustrated, an operation of forming the external terminals 28 (See FIG. 3) at distal ends of the connective conductors 20 may be performed before or after the operation of cutting the board strip 10. Here, the external terminals 28 may be formed in various forms such as a bump form, a solder ball form, a pad form, or the like.

The electronic device module 200 according to the present exemplary embodiment illustrated in FIG. 6A may be completed through the above-mentioned processes.

Meanwhile, in a case in which a problem occurring due to exposure of the plating lines is ignorable, the outer molded part may be omitted so that portions of the plating lines are exposed externally. In this case, the molded part may include only the inner molded part or may include only the inner molded part and the first molded part.

FIG. 11 is a bottom perspective view schematically illustrating an electronic device module according to another exemplary embodiment in the present disclosure.

Referring to FIG. 11, in an electronic device module 300 according to the present exemplary embodiment, a material of a molded part (inner molded part) formed in a primary molding process and a material of molded parts (first molded part and outer molded part) formed in a secondary molding process may be different from each other.

Therefore, the entirety of the first molded part 31 formed on the upper surface of the board 10 may be formed of the same material, and the inner molded part 35a and the outer molded part 35b of the second molded part 35 formed on the lower surface of the board 10 may be formed of different materials. In addition, the first molded part 31 and the outer molded part 35b of the second molded part 35 may be formed of the same material.

As described above, the electronic device module according to the present exemplary embodiment may be modified in various forms.

As set forth above, in the electronic device module according to the exemplary embodiments of the present disclosure, the electronic devices may be mounted on both surfaces of the board and be sealed by the molded part. Therefore, many devices may be mounted in one electronic device module and be easily protected from the external environment.

In addition, since the connective conductors are formed in the molded part in the plating scheme, they may be easily manufactured. Further, since the plating lines may be completely embedded in the electronic device module, if necessary, concentration of an electric field in the vicinity of the plating lines may be prevented.

While exemplary embodiments have been shown and described above, it will be apparent to those skilled in the art that modifications and variations could be made without departing from the scope of the present invention as defined by the appended claims.

What is claimed is:

1. An electronic device module comprising:
a board including one or more external connection electrodes and plating lines extending from the external connection electrodes by a predetermined distance;
one or more electronic devices mounted on the board;
a molded part sealing the electronic devices; and
a plurality of connective conductors extending from the external connection electrodes and penetrating through the molded part to be disposed within the molded part.

2. The electronic device module of claim 1, wherein the molded part is formed of an epoxy molding compound (EMC).

3. The electronic device module of claim 1, wherein distal ends of the plating lines are exposed to the exterior of the board.

4. The electronic device module of claim 1, wherein the entirety of the plating lines is disposed within the molded part.

5. The electronic device module of claim 1, wherein a height of the connective conductor is equal to one to two times a maximum width of the connective conductor.

6. The electronic device module of claim 5, wherein the height of the connective conductor is 200 μm or more.

7. The electronic device module of claim 1, wherein the connective conductors interlock with the molded part through a mechanical interlocking mechanism.

8. The electronic device module of claim 1, wherein the molded part is provided on both surfaces of the board.

9. The electronic device module of claim 1, further comprising external terminals bonded to the connective conductors at distal ends thereof.

10. A method of manufacturing an electronic device module, the method comprising:
preparing a board on which plating lines are formed;
mounting one or more devices on the board;
forming a molded part sealing the devices;
forming via holes in the molded part; and
forming connective conductors in the via holes by using a plating method employing the plating lines.

11. The method of claim 10, wherein the board is a board strip on which a plurality of individual module mounting regions are formed, and
one or more external connection electrodes are formed within the individual module mounting regions,
conductive patterns are formed outside of the individual module mounting regions, and
the plating lines connect the one or more external connection electrodes and the conductive patterns to each other.

12. The method of claim 11, further comprising, after the forming of the connective conductors, cutting the board strip on the basis of the individual module mounting regions,
wherein the conductive patterns are removed during the cutting of the board strip.

13. The method of claim 12, wherein distal ends of the plating lines are exposed to the exterior of the molded part through cut surfaces of the board strip.

14. The method of claim 10, wherein a depth of the via hole is equal to one to two times a maximum width of the via hole.

15. The method of claim 10, wherein the via hole has a depth of 200 μm or more.

16. The method of claim 10, wherein the forming of the via holes includes increasing a level of roughness of inner surfaces of the via holes using laser processing.

17. The method of claim 10, wherein the connective conductors are formed by an electroplating process without an electroless plating process.

18. The method of claim 10, wherein the one or more external connection electrodes are electrically connected to the plating lines, and
the one or more external connection electrodes are exposed to the exterior of the board through the via holes.

19. The method of claim 18, wherein the forming of the connective conductors is performed by applying a current to the one or more external connection electrodes through the plating lines to grow the connective conductors from the one or more external connection electrodes and filling the connective conductors in the via holes.

20. The method of claim 19, wherein the forming of the connective conductors includes allowing the connective conductors to interlock with inner surfaces of the via holes through a mechanical interlocking mechanism.

21. The method of claim 10, wherein the molded part is formed using an epoxy molding compound (EMC), and
the connective conductors are formed through copper electroplating.

22. The method of claim 10, further comprising forming external terminals on the connective conductors.

23. The method of claim 10, wherein the step of forming the molded part includes forming an inner molded part while allowing at least portions of the plating lines to be exposed to the exterior thereof.

24. The method of claim 23, wherein the connective conductors are formed by allowing a metal frame to contact the plating lines exposed to the exterior of the inner molded part and then applying a current to the metal frame.

25. The method of claim 23, further comprising, after the forming of the connective conductors, forming an outer molded part outside of the inner molded part to allow the plating lines to be embedded in the outer molded part.

26. The method of claim 25, wherein the outer molded part is formed by using a molding resin which is introduced to one surface of the board while a new molded part is formed on the other surface of the board.

27. The method of claim 26, wherein the board is a board strip on which a plurality of individual module mounting regions are formed,
one or more through-holes are formed between the individual module mounting regions, and
the molding resin is introduced to one surface of the board through the through-holes.

28. A method of manufacturing an electronic device module, the method comprising:
preparing a board on which plating lines are formed;
mounting one or more devices on one surface of the board;
forming an inner molded part sealing the devices while allowing portions of the plating lines to be exposed to the exterior of the inner molded part;
forming via holes in the inner molded part;
forming connective conductors in the via holes by using a plating method employing the plating lines; and
forming an outer molded part on one surface of the board to embed the plating lines completely in the outer molded part.

29. The method of claim 28, wherein the step of forming the outer molded part includes:
mounting one or more devices on the other surface of the board; and
forming a first molded part by injecting a molding resin into the other surface of the board, wherein
the outer molded part is formed by using the molding resin which is introduced into one surface of the board.

30. An electronic device module comprising:
a board including one or more external connection electrodes and plating lines extending from the external connection electrodes by a predetermined distance;
one or more electronic devices mounted on one surface of the board;
an inner molded part sealing the electronic devices while allowing portions of the plating lines to be exposed to the exterior thereof; and
a plurality of connective conductors extending from the external connection electrodes and penetrating through the inner molded part to be disposed within the inner molded part.

31. The electronic device module of claim 30, further comprising an outer molded part allowing the plating lines exposed to the exterior of the inner molded part to be embedded therein.

32. The electronic device module of claim 31, wherein the inner molded part and the outer molded part are formed of different materials.

33. The electronic device module of claim 31, wherein the inner molded part and the outer molded part are formed of the same material.

34. The electronic device module of claim 31, further comprising a first molded part formed on the other surface of the board.

35. The electronic device module of claim 34, wherein the outer molded part and the first molded part are formed of the same material.
